(19) United States
(12) Patent Application Publication
(10) Pub. No.: US 2025/0089414 A1
(43) Pub. Date: Mar. 13, 2025

(54) SYSTEMS AND METHODS FOR IMPROVED DISPLAYS

(71) Applicant: Meta Platforms Technologies, LLC, Menlo Park, CA (US)

(72) Inventors: Salim Boutami, Seattle, WA (US); Yaniv Vinish, Carrigtwohill (IE); Stephan Lutgen, Dresden (DE)

(21) Appl. No.: 18/464,201

(22) Filed: Sep. 9, 2023

(51) Int. Cl. H01L 33/58

(52) U.S. Cl. CPC H10H 20/855; H10H 20/872

(57) ABSTRACT

An optical element includes a planar body having a circular profile including a plurality of annuli of decreasing width with increasing radius, where the circular profile includes a sequential arrangement of: (a) a first annulus including alternating azimuthal segments of high and low refractive index materials, (b) a second annulus including the high refractive index material, (c) a third annulus including alternating azimuthal segments of the high and low refractive index materials, and (d) a fourth annulus including the low refractive index material. The optical element may be configured to increase the light extraction efficiency and directionality of light output from a light emitting diode.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 shows the incorporation of a grating ring-modified LED into example optical systems according to various embodiments.

FIG. 2 is a schematic diagram showing the configuration of grating ring-integrated LEDs according to some embodiments.

FIG. 3 is a simplified top-down plan view showing a grating ring configuration for improving light extraction from an LED according to various embodiments.

FIG. 4 shows modeled results for a grating structure configured to improve light extraction from an LED according to various embodiments.

FIG. 5 shows modeled results for example grating structures for improving light extraction from an LED with and without a co-integrated lens according to some embodiments.

FIG. 6 shows modeled results for example grating structures having different cell thicknesses according to certain embodiments.

FIG. 7 shows example modeled grating structures for improving light extraction from an LED according to some embodiments.

FIG. 8 is a schematic diagram showing the configuration of a grating ring-integrated LED according to further embodiments.

FIG. 9 is an illustration of exemplary augmented-reality glasses that may be used in connection with embodiments of this disclosure.

FIG. 10 is an illustration of an exemplary virtual-reality headset that may be used in connection with embodiments of this disclosure.

FIG. 11 is a schematic illustration showing the operation of a diffractive waveguide according to some embodiments.

FIG. 12 is a visual representation of the critical angle and grazing angle conditions for an example diffractive waveguide according to some embodiments.

FIG. 13 is a visual representation of the critical angle and grazing angle conditions showing the effect of refractive index on field-of-view for an example diffractive waveguide according to some embodiments.

FIG. 14 shows k-space renderings for isotropic optical materials, anisotropic optical materials, and hyperbolic metamaterials according to certain embodiments.

FIG. 15 shows the impact of hyperbolic metamaterials on the field-of-view of a refractive waveguide according to some embodiments.

FIG. 16 shows simulation data for the k-space renderings of FIG. 15 according to certain embodiments.

FIG. 17 shows simulation data for the k-space renderings of FIG. 15 according to further embodiments.

FIG. 18 shows the impact of hyperbolic metamaterials on the field-of-view of a refractive waveguide according to further embodiments.

FIG. 19 shows simulation data for the k-space renderings of FIG. 18 according to some embodiments.

FIG. 20 shows the impact of hyperbolic metamaterials on the FOV in 2D according to certain embodiments.

FIG. 21 shows the impact of hyperbolic metamaterials on the FOV in 2D according to further embodiments.

FIG. 22 illustrates example hyperbolic metamaterial configurations according to some embodiments.

FIG. 23 shows an example apparatus for manufacturing a single crystal organic solid crystal according to some embodiments.

FIGS. 24A-F are cross-sectionals view of a crystal growth chamber showing the formation of an organic solid crystal having a structured surface according to some embodiments.

FIG. 25 is an SEM micrograph showing an organic solid crystal having a structured surface according to certain embodiments

FIG. 26 is an SEM micrograph of a channel filled with OSC material according to some embodiments.

FIG. 27 includes a review of various considerations in the design and manufacture of a large area GRIN LC lens.

FIG. 28 is a description of example GRIN LC lens architectures according to some embodiments.

FIG. 29 is a description of GRIN LC lens architectures according to further embodiments.

FIG. 30 includes modeling results for GRIN LC lenses according to various embodiments.

FIG. 31 shows plots of optical performance for various GRIN LC lens architectures according to some embodiments.

FIG. 32 is a plot of the total phase and the phase difference component as a function of radial position for example GRIN LC lenses according to certain embodiments.

FIG. 33 shows the optical performance for parabolic and hyperbolic phase elements according to some embodiments.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

### LED with Grating Rings for Improved Light Extraction Efficiency and Directivity

A light emitting diode (LED) is a semiconductor device that emits light in response to an applied electric current or an applied voltage. During operation, electrons in the semiconductor recombine with holes, releasing energy in the form of photons. The color of the emitted light, which corresponds to the energy of the photons, is related to the energy required for electrons to cross the band gap of the semiconductor.

The performance of a light-emitting diode may be evaluated by two figures of merit, i.e., the internal quantum efficiency of the device's active region and the efficiency of light extraction therefrom. The internal quantum efficiency (IQE) may be defined as the time-integrated ratio of the number of photons emitted from the active region to the number of electrons injected into the light-emitting diode (LED), whereas the light extraction efficiency (LEE) may be determined from the ratio of the number of photons emitted from the LED to the number of photons generated inside the LED.

As will be appreciated, the refractive index of most LED semiconductor materials is greater than the refractive index of the medium into which light from the LED is coupled. This large index difference may be a principal source of LED inefficiency, where a substantial portion of produced light may be reflected back into the semiconductor and absorbed and converted to heat. In many LED devices, greater than half of the emitted light is reflected back at the LED-package and package-air interfaces.

In addition, typically only a portion of the light emitted by an LED is collected by an accompanying optical system (e.g., projector). In such systems, light may be collected from within a cone of ±18.5°, for example. Insomuch as the emission by dipoles representing emitters in the quantum wells is typically isotropic, and is therefore not intrinsically collimated, it would be advantageous to source LED light having a high light extraction efficiency that is also directed along a single optical axis.

In accordance with various embodiments, a light emitting diode may include a subwavelength structure located in the path of its emitted photons. The subwavelength structure may include a planar grating characterized by a plurality of annular rings. The annular rings may include a single material having a uniform refractive index or plural materials arranged to have a spatially variable index. In the example of an annulus including two materials, one material may have a high refractive index (nₕ) and the other material may have a low refractive index (nₗ). The high refractive index may be equivalent or substantially equivalent to the refractive index of a semiconductor layer forming the LED. By way of illustration, a high refractive index material may include GaAs (n≈3.6) and a low refractive index material may include silicon nitride, (n≈2). An example grating structure may include a radial progression of a composite ring, a high refractive index ring, a composite ring, a low refractive index ring, etc. Within a composite ring, the structure may include a quasiperiodic azimuthal arrangement of alternating high and low refractive index materials.

The annular grating architecture may advantageously create continuous phase variation along the radial direction. By obviating the phase discontinuity that may be encountered in comparative structures, such as Fresnel structures, unidirectional scattering may be avoided. Moreover, the disclosed annular grating architecture may promote light extraction from the LED and especially the directional extraction of light where the period of the grating is more than half the wavelength of the surrounding medium, but less than the wavelength of the surrounding medium. In certain examples, the light extraction efficiency may be increased by 100% or more relative to μLEDs having μlens optics only.

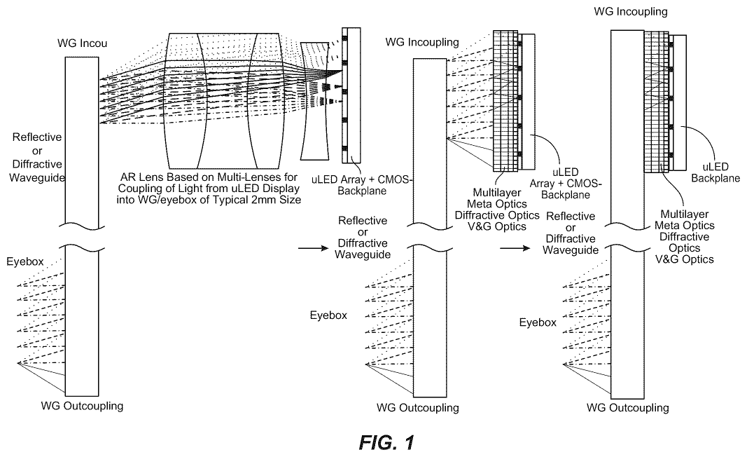

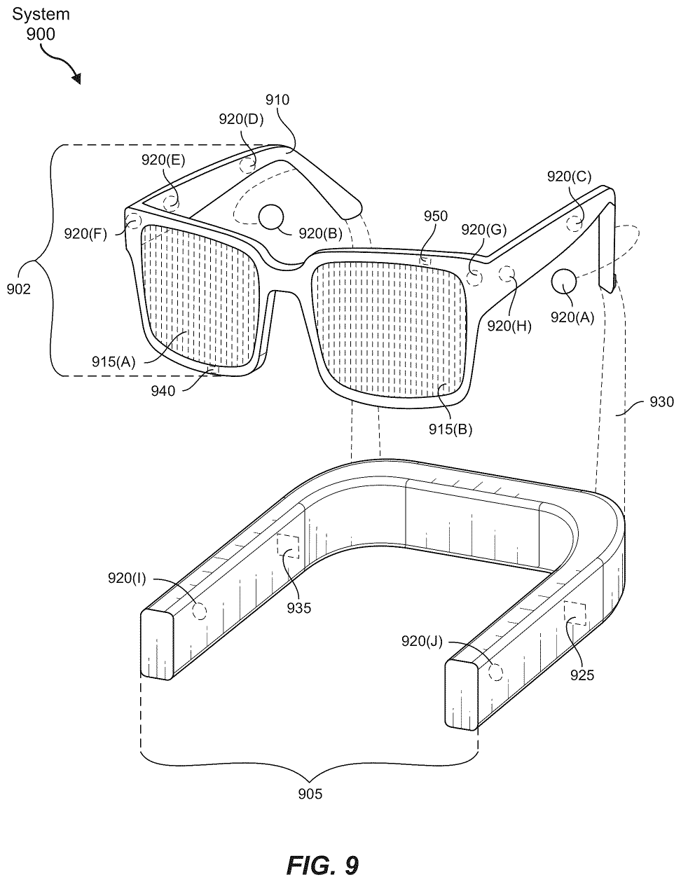

The following will provide, with reference to FIGS. 1-10, detailed descriptions of methods and apparatus for generating collimated LED light output having an elevated light extraction efficiency (LEE). The discussion associated with FIGS. 1-8 includes a description of apparatus and methods for improving the extraction efficiency of light emitted from a light emitting diode, such as a micro-LED. The discussion associated with FIGS. 9 and 10 relates to exemplary virtual reality and augmented reality devices that may include one or more modified LEDs as disclosed herein.

A planar optical element having a subwavelength architecture and including a semi-periodic grating structure may be positioned proximate to the output of an LED to improve the light extraction efficiency and collimation of emitted light. In certain instantiations, the optical element may be configured to enable beam steering of μLED light emission from 1D or 2D μLED arrays for more efficient light coupling, e.g., from a larger μLED display into smaller collimation optics, and more uniform illumination. With reference to FIG. 1, compact multistage optics that include a planar optical element may replace bulky and inefficient AR optics (left) to improve light coupling between a μLED display and a human eye (middle) or, in further embodiments, may be co-integrated with a directly bonded display on a waveguide to decrease reflective losses and even compensate for non-uniformities in the waveguide (right).

Referring to FIG. 2, shown schematically are variations in an optical system that includes a planar optical element 201 as disclosed herein. A lens 202 may be omitted (left) or included (right) in the optical system. The optical element 201 may be placed proximate to the output of a light emitting diode 210, where the total focal length (H) of the system may be measured with respect to the top aperture of the LED (rather than the location of the quantum wells). Shown quantitatively in FIG. 2 for each system is the phase profile, Δφ (x,y), to collimate light from the LED.

Turning to FIG. 3, shown is a top-down plan view of optical element 201. In the illustrated embodiment, optical element 201 may be formed from two materials having disparate refractive indices, i.e., where one material has a high refractive index (nh) and one material has a low refractive index (nl), although more than a pair of materials may be used.

Optical element 201 may have an annular ring structure. Each ring may include (i) a single high refractive index material or a single low refractive index material, or (ii) a composite structure including alternating azimuthal segments of high and low refractive index materials. That is, composite rings having both high and low refractive index segments may have a subwavelength quasi-periodic azimuthal structuration and a fill factor of approximately 50%. Along a radial direction, an example structure may include a sequential arrangement of a composite ring, a high refractive index ring, a composite ring, a low refractive index ring, etc. In particular embodiments, and as illustrated in FIG. 3, the annular width of each successive ring may decrease with increasing radius. Such a structure may be fabricated using semiconductor processing methods, including deposition, photolithography and etching, and chemical mechanical polishing techniques.

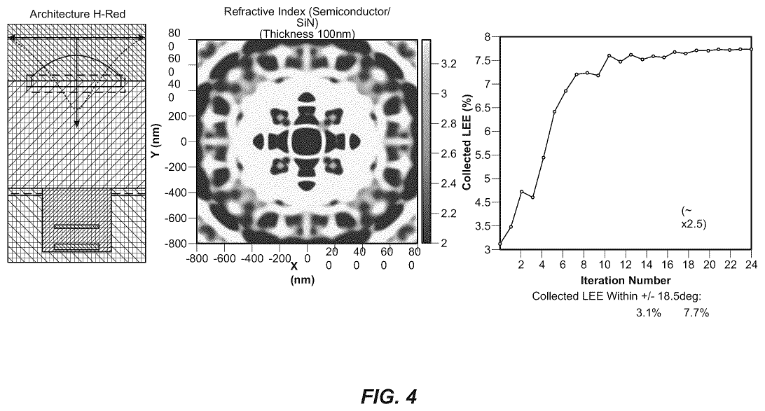

An adjoint optimization method may be used to design and validate the presently-disclosed grating architectures for extracting and collimating light. An adjoint method formulates the gradient of a function towards its parameters in a constraint optimization form. For light extraction from an LED, adjoint simulation may include sending a Gaussian beam of normal emission from air backwards into the LED. From the forward field (dipole emission) and the adjoint field (Gaussian mode sent backwards) the gradient of a figure of merit with respect to permittivity in the design region may be obtained, which may be used to modify the permittivity in a successive iteration, and so on. Adjoint optimization results for a 100 nm thick structure are shown in FIG. 4. The modeled design includes a grating ring architecture having a 100% improvement in light extraction efficiency relative to comparative light extraction structures.

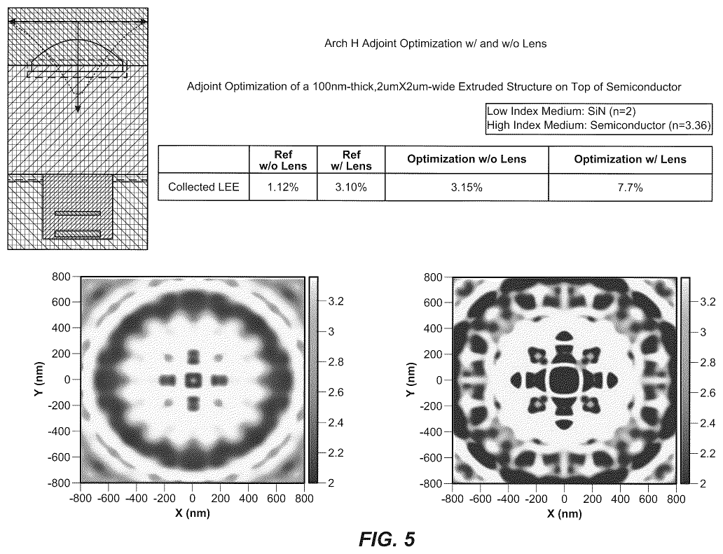

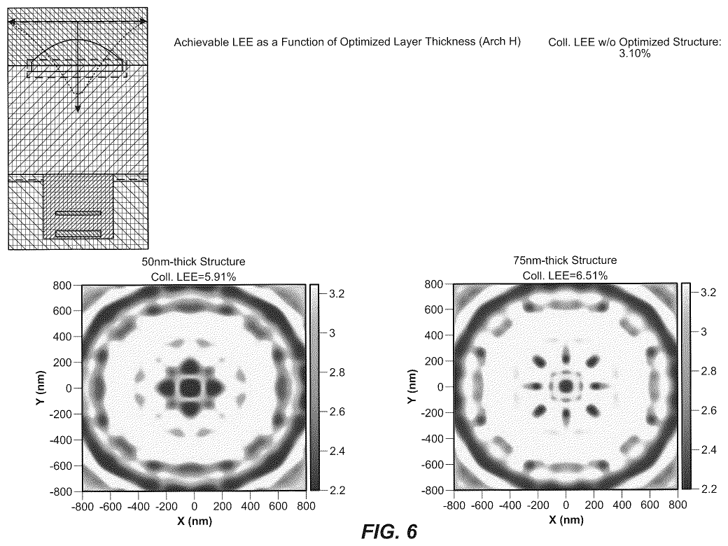

For improving the structuration of the grating, designed and modeled structures omitting and including an overlying lens are shown in FIG. 5. As will be appreciated, relative to a lens-free configuration, an overlying lens may generate a beneficially slower phase profile that allows for a thinner and more efficient ring structure. In this vein, light extraction efficiency and manufacturability may each influence the grating design, and especially the grating thickness. For instance, if the grating is too thin, the phase spatial profile for collimation may require a rapid lateral refractive index change and any subwavelength structured ring will therefore need to have a very small width. Such features may be challenging to fabricate due to lithography constraints. On the other hand, if the grating is too thick, the features may be extended to higher aspect ratios where small features will have a large phase shift. Grating structures and corresponding light extraction efficiencies for structure thicknesses ranging from 50 nm to 200 nm are shown in FIG. 6.

In some cases, adjoint optimization may generate a structure that is not perfectly binary, as small permittivity changes may be made in each iteration. To generate a structure that may be fabricated using 2 materials (e.g., first material deposition, lithography, etch, second material deposition, and planarization) a binary structure including only the lowest and highest refractive index may be desired.

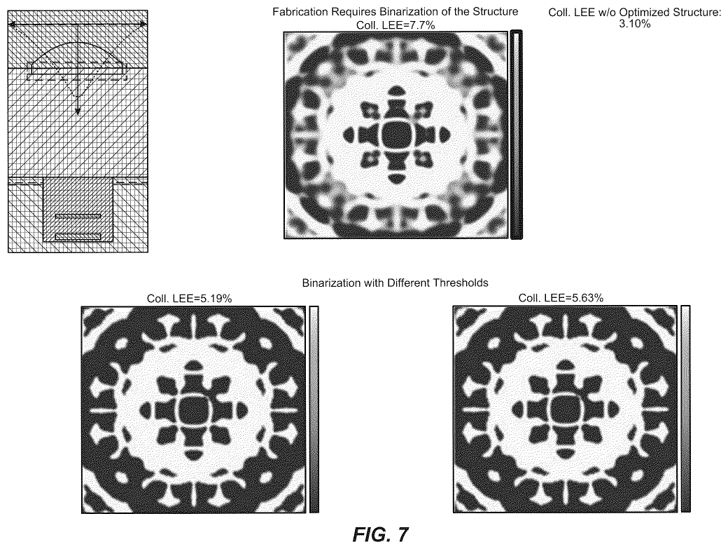

Binarization may be achieved by defining a threshold index above which any permittivity is set to maximum and below which any permittivity is set to minimum. With reference to FIG. 7, which illustrates structures obtained using different binarization thresholds, LEE values remain high even after binarization (>6.5% for some cases) independent of the thresholding.

In some embodiments, a grating architecture may include a combination of different stacked optical elements, such as one or multiple meta-optical layers, or combinations of meta-optical layers with microlenses for very small pitch (e.g., 1 to 20 μm) and densely-packed μLED (1D or 2D) arrays.

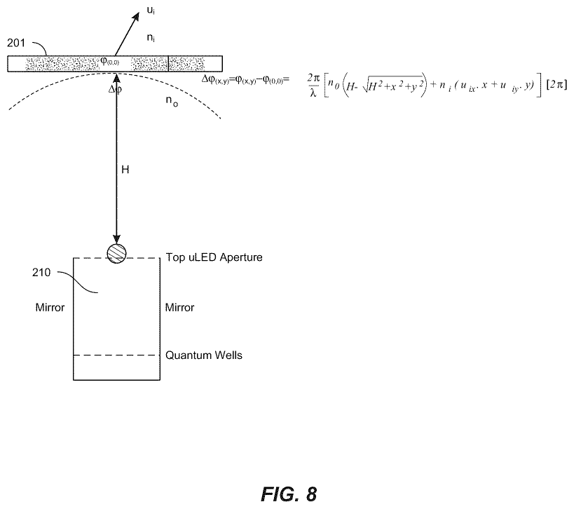

According to further embodiments, the disclosed grating architectures may be beneficial beyond improving LEE and collimation metrics, and may also be used to control beam angle, beam splitting, focus and de-focus, etc. In one instantiation, asymmetrical grating rings may enable light extraction and beam steering along a non-normal direction, e.g., pixel-by-pixel in order to match the chief ray angle of a projector. Referring to FIG. 8, a phase profile may be designed to achieve beam steering in medium (i) with a direction unit vector ui, e.g., by adding a slope to the phase profile given by the direction ui.

Disclosed is an optical element that may be disposed proximate to the output of an LED to improve light extraction efficiency (LEED and directivity of emitted light. The optical element may include a grating having a planar architecture composed of plural of concentric rings. Each ring may include one of (i) a high refractive index material, (ii) a low refractive index material, or (iii) a composite structure having high and low refractive index materials arranged in alternating azimuthal segments. A composite ring may have a fill factor of high and low refractive index materials of approximately 0.5. An example grating may include a radial sequencing of a composite ring, a high refractive index ring, a composite ring, a low refractive index ring, etc. In particular embodiments, the annular width of each successive ring may decrease with increasing radius. An optical element may include a combination of different stacked structures, such as one or multiple meta-optical layers, or combinations of meta-optical layers with microlenses.

### EXAMPLE EMBODIMENTS

Example 1: An optical element has a planar body with a circular profile including a plurality of annuli of decreasing width with increasing radius, where the circular profile includes a sequential arrangement of (a) a first annulus including alternating azimuthal segments of high and low refractive index materials, (b) a second annulus including the high refractive index material, (c) a third annulus including alternating azimuthal segments of the high and low refractive index materials, and (d) a fourth annulus including the low refractive index material.

Example 2: The optical element of Example 1, where a fill factor of the first annulus is approximately 0.5 and a fill factor of the third annulus is approximately 0.5.

Example 3: The optical element of any of Examples 1 and 2, where the second annulus consists essentially of the high refractive index material and the fourth annulus consists essentially of the low refractive index material.

Example 4: The optical element of any of Examples 1-3, where the high refractive index is greater than approximately 3.2 and the low refractive index is less than approximately 2.6.

Example 5: The optical element of any of Examples 1-4, where a center of the circular profile includes the low refractive index material.

Example 6: A light emitting diode package including the optical element of any of Examples 1-5.

Example 7: The light emitting diode package of Example 6, where the circular profile is centered about an optical axis of the light emitting diode.

Example 8: An optical element includes a planar body having a circular profile including a plurality of annuli of decreasing width with increasing radius, where the circular profile includes an alternating arrangement of structured and unstructured annuli, the structured annuli having alternating azimuthal segments of high and low refractive index materials and the unstructured annuli including a high refractive index material or a low refractive index material.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (e.g., augmented-reality system 900 in FIG. 9) or that visually immerses a user in an artificial reality (e.g., virtual-reality system 1000 in FIG. 10). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 9, augmented reality system 900 may include an eyewear device 902 with a frame 910 configured to hold a left display device 915(A) and a right display device 915(B) in front of a user's eyes. Display devices 915(A) and 915(B) may act together or independently to present an image or series of images to a user. While augmented-reality system 900 includes two displays, embodiments of this disclosure may be implemented in augmented-reality systems with a single NED or more than two NEDs.

In some embodiments, augmented-reality system 900 may include one or more sensors, such as sensor 940. Sensor 940 may generate measurement signals in response to motion of augmented-reality system 900 and may be located on substantially any portion of frame 910. Sensor 940 may represent a position sensor, an inertial measurement unit (IMU), a depth camera assembly, a structured light emitter and/or detector, or any combination thereof. In some embodiments, augmented-reality system 900 may or may not include sensor 940 or may include more than one sensor. In embodiments in which sensor 940 includes an IMU, the IMU may generate calibration data based on measurement signals from sensor 940. Examples of sensor 940 may include, without limitation, accelerometers, gyroscopes, magnetometers, other suitable types of sensors that detect motion, sensors used for error correction of the IMU, or some combination thereof.

Augmented-reality system 900 may also include a microphone array with a plurality of acoustic transducers 920(A)-920(J), referred to collectively as acoustic transducers 920. Acoustic transducers 920 may be transducers that detect air pressure variations induced by sound waves. Each acoustic transducer 920 may be configured to detect sound and convert the detected sound into an electronic format (e.g., an analog or digital format). The microphone array in FIG. 9 may include, for example, ten acoustic transducers: 920(A) and 920(B), which may be designed to be placed inside a corresponding ear of the user, acoustic transducers 920(C), 920(D), 920(E), 920(F), 920(G), and 920(H), which may be positioned at various locations on frame 910, and/or acoustic transducers 920(I) and 920(J), which may be positioned on a corresponding neckband 905.

In some embodiments, one or more of acoustic transducers 920(A)-(F) may be used as output transducers (e.g., speakers). For example, acoustic transducers 920(A) and/or 920(B) may be earbuds or any other suitable type of headphone or speaker.

The configuration of acoustic transducers 920 of the microphone array may vary. While augmented-reality system 900 is shown in FIG. 9 as having ten acoustic transducers 920, the number of acoustic transducers 920 may be greater or less than ten. In some embodiments, using higher numbers of acoustic transducers 920 may increase the amount of audio information collected and/or the sensitivity and accuracy of the audio information. In contrast, using a lower number of acoustic transducers 920 may decrease the computing power required by an associated controller 950 to process the collected audio information. In addition, the position of each acoustic transducer 920 of the microphone array may vary. For example, the position of an acoustic transducer 920 may include a defined position on the user, a defined coordinate on frame 910, an orientation associated with each acoustic transducer 920, or some combination thereof.

Acoustic transducers 920(A) and 920(B) may be positioned on different parts of the user's ear, such as behind the pinna, behind the tragus, and/or within the auricle or fossa. Or, there may be additional acoustic transducers 920 on or surrounding the ear in addition to acoustic transducers 920 inside the ear canal. Having an acoustic transducer 920 positioned next to an ear canal of a user may enable the microphone array to collect information on how sounds arrive at the ear canal. By positioning at least two of acoustic transducers 920 on either side of a user's head (e.g., as binaural microphones), augmented-reality device 900 may simulate binaural hearing and capture a 3D stereo sound field around about a user's head. In some embodiments, acoustic transducers 920(A) and 920(B) may be connected to augmented-reality system 900 via a wired connection 930, and in other embodiments acoustic transducers 920(A) and 920(B) may be connected to augmented-reality system 900 via a wireless connection (e.g., a Bluetooth connection). In still other embodiments, acoustic transducers 920(A) and 920(B) may not be used at all in conjunction with augmented-reality system 900.

Acoustic transducers 920 on frame 910 may be positioned along the length of the temples, across the bridge, above or below display devices 915(A) and 915(B), or some combination thereof. Acoustic transducers 920 may be oriented such that the microphone array is able to detect sounds in a wide range of directions surrounding the user wearing the augmented-reality system 900. In some embodiments, an optimization process may be performed during manufacturing of augmented-reality system 900 to determine relative positioning of each acoustic transducer 920 in the microphone array.

In some examples, augmented-reality system 900 may include or be connected to an external device (e.g., a paired device), such as neckband 905. Neckband 905 generally represents any type or form of paired device. Thus, the following discussion of neckband 905 may also apply to various other paired devices, such as charging cases, smart watches, smart phones, wrist bands, other wearable devices, hand-held controllers, tablet computers, laptop computers, other external compute devices, etc.

As shown, neckband 905 may be coupled to eyewear device 902 via one or more connectors. The connectors may be wired or wireless and may include electrical and/or non-electrical (e.g., structural) components. In some cases, eyewear device 902 and neckband 905 may operate independently without any wired or wireless connection between them. While FIG. 9 illustrates the components of eyewear device 902 and neckband 905 in example locations on eyewear device 902 and neckband 905, the components may be located elsewhere and/or distributed differently on eyewear device 902 and/or neckband 905. In some embodiments, the components of eyewear device 902 and neckband 905 may be located on one or more additional peripheral devices paired with eyewear device 902, neckband 905, or some combination thereof.

Pairing external devices, such as neckband 905, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 900 may be provided by a paired device or shared between a paired device and an eyewear device, thus reducing the weight, heat profile, and form factor of the eyewear device overall while still retaining desired functionality. For example, neckband 905 may allow components that would otherwise be included on an eyewear device to be included in neckband 905 since users may tolerate a heavier weight load on their shoulders than they would tolerate on their heads. Neckband 905 may also have a larger surface area over which to diffuse and disperse heat to the ambient environment. Thus, neckband 905 may allow for greater battery and computation capacity than might otherwise have been possible on a stand-alone eyewear device. Since weight carried in neckband 905 may be less invasive to a user than weight carried in eyewear device 902, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 905 may be communicatively coupled with eyewear device 902 and/or to other devices. These other devices may provide certain functions (e.g., tracking, localizing, depth mapping, processing, storage, etc.) to augmented-reality system 900. In the embodiment of FIG. 9, neckband 905 may include two acoustic transducers (e.g., 920(I) and 920(J)) that are part of the microphone array (or potentially form their own microphone subarray). Neckband 905 may also include a controller 925 and a power source 935.

Acoustic transducers 920(I) and 920(J) of neckband 905 may be configured to detect sound and convert the detected sound into an electronic format (analog or digital). In the embodiment of FIG. 9, acoustic transducers 920(I) and 920(J) may be positioned on neckband 905, thereby increasing the distance between the neckband acoustic transducers 920(I) and 920(J) and other acoustic transducers 920 positioned on eyewear device 902. In some cases, increasing the distance between acoustic transducers 920 of the microphone array may improve the accuracy of beamforming performed via the microphone array. For example, if a sound is detected by acoustic transducers 920(C) and 920(D) and the distance between acoustic transducers 920(C) and 920(D) is greater than, e.g., the distance between acoustic transducers 920(D) and 920(E), the determined source location of the detected sound may be more accurate than if the sound had been detected by acoustic transducers 920(D) and 920(E).

Controller 925 of neckband 905 may process information generated by the sensors on neckband 905 and/or augmented-reality system 900. For example, controller 925 may process information from the microphone array that describes sounds detected by the microphone array. For each detected sound, controller 925 may perform a direction-of-arrival (DOA) estimation to estimate a direction from which the detected sound arrived at the microphone array. As the microphone array detects sounds, controller 925 may populate an audio data set with the information. In embodiments in which augmented-reality system 900 includes an inertial measurement unit, controller 925 may compute all inertial and spatial calculations from the IMU located on eyewear device 902. A connector may convey information between augmented-reality system 900 and neckband 905 and between augmented-reality system 900 and controller 925. The information may be in the form of optical data, electrical data, wireless data, or any other transmittable data form. Moving the processing of information generated by augmented-reality system 900 to neckband 905 may reduce weight and heat in eyewear device 902, making it more comfortable to the user.

Power source 935 in neckband 905 may provide power to eyewear device 902 and/or to neckband 905. Power source 935 may include, without limitation, lithium ion batteries, lithium-polymer batteries, primary lithium batteries, alkaline batteries, or any other form of power storage. In some cases, power source 935 may be a wired power source. Including power source 935 on neckband 905 instead of on eyewear device 902 may help better distribute the weight and heat generated by power source 935.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1000 in FIG. 10, that mostly or completely covers a user's field of view. Virtual-reality system 1000 may include a front rigid body 1002 and a band 1004 shaped to fit around a user's head. Virtual-reality system 1000 may also include output audio transducers 1006(A) and 1006(B). Furthermore, while not shown in FIG. 10, front rigid body 1002 may include one or more electronic elements, including one or more electronic displays, one or more inertial measurement units (IMUs), one or more tracking emitters or detectors, and/or any other suitable device or system for creating an artificial reality experience.

Artificial-reality systems may include a variety of types of visual feedback mechanisms. For example, display devices in augmented-reality system 900 and/or virtual-reality system 1000 may include one or more liquid crystal displays (LCDs), light emitting diode (LED) displays, organic LED (OLED) displays, digital light project (DLP) micro-displays, liquid crystal on silicon (LCoS) micro-displays, and/or any other suitable type of display screen. Artificial-reality systems may include a single display screen for both eyes or may provide a display screen for each eye, which may allow for additional flexibility for varifocal adjustments or for correcting a user's refractive error. Some artificial-reality systems may also include optical subsystems having one or more lenses (e.g., conventional concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some artificial-reality systems may include one or more projection systems. For example, display devices in augmented-reality system 900 and/or virtual-reality system 1000 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

Artificial-reality systems may also include various types of computer vision components and subsystems. For example, augmented reality system 900 and/or virtual-reality system 1000 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

Artificial-reality systems may also include one or more input and/or output audio transducers. In the examples shown in FIG. 10, output audio transducers 1006(A) and 1006(B) may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

While not shown in FIG. 9, artificial-reality systems may include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

### Wide Field-of-View Waveguide Displays Using Hyperbolic Metamaterials

The present disclosure relates generally to waveguide displays having a wide field-of-view and more specifically to refractive waveguide displays supporting an arbitrarily wide field-of-view (FOV) through the use of hyperbolic metamaterials.

As will be appreciated, comparative waveguides may use transparent dielectric materials as substrates to guide light into a user's eyes. However, in such devices, the supported FOV is constrained by the refractive index of the waveguide substrate due to the limited k-space, where field-of-view is inversely proportional to the spacing between samples in k-space, i.e., Δk=1/FOV. A typical diffractive waveguide using high index glass with a refractive index of 2 will support only a 30° diagonal FOV across the complete visible spectrum.

As disclosed herein, by using hyperbolic metamaterials for the waveguide substrate and indefinitely spanning k-space, a waveguide display may be manufactured having an arbitrarily wide FOV. Detailed demonstrations show hyperbolic metamaterials support an arbitrarily wide FOV in 1D. Moreover, 3D plots of hyperbolic k-vectors show that hyperbolic metamaterials also support an arbitrarily wide FOV in 2D because the support of the k-vectors extends indefinitely in the x-y plane. In addition, hyperbolic metamaterials may support an arbitrarily wide FOV for a specific operating wavelength and/or across all colors of the visible spectrum despite the phenomenon of grating diffraction dispersion.

Hyperbolic metamaterials (HMMs) are a class of subwavelength structures that may be characterized by a unique hyperbolic dispersion. In such materials, the sign of the tangential permittivity opposes that of the vertical permittivity for the transverse magnetic (TM) polarization mode. The iso-frequency curves of hyperbolic metamaterials can be classified into two types based on the sign of the vertical permittivity and the tangential permittivity. If the vertical permittivity is negative, the medium is type-I, and if the tangential permittivity is negative, the medium is type-II. Type-I hyperbolic metamaterials support the propagation of electromagnetic waves with both small and large wave vectors, whereas type-II hyperbolic metamaterials support propagation only for electromagnetic waves with large wave vectors.

Hyperbolic dispersion may be achieved using both thin film and nanowire structures. A stratiform hyperbolic metamaterial, for instance, may include multiple units of a symmetrical metal-dielectric bilayer stacked to have an equivalent refractive index. Example metals suitable for forming a thin film multilayer include gold and silver. Aluminum oxide may be a suitable dielectric material to form a stacked hyperbolic metamaterial. According to some embodiments, the substrate for a diffractive waveguide may include a metamaterial that is composed of stacks of symmetrical layers configured to couple a diffracted wave into a horizontally propagating plasmonic wave. According to further embodiments, nanowire HMM structures may include an array of metallic nanorods embedded in a dielectric matrix. In a substrate for a diffractive waveguide, the plural nanorods may be aligned along a single direction.

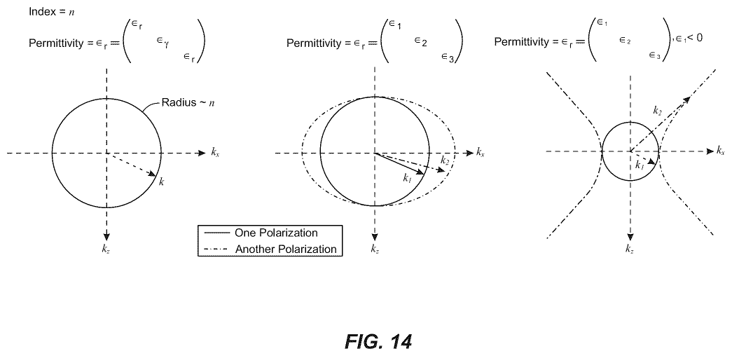

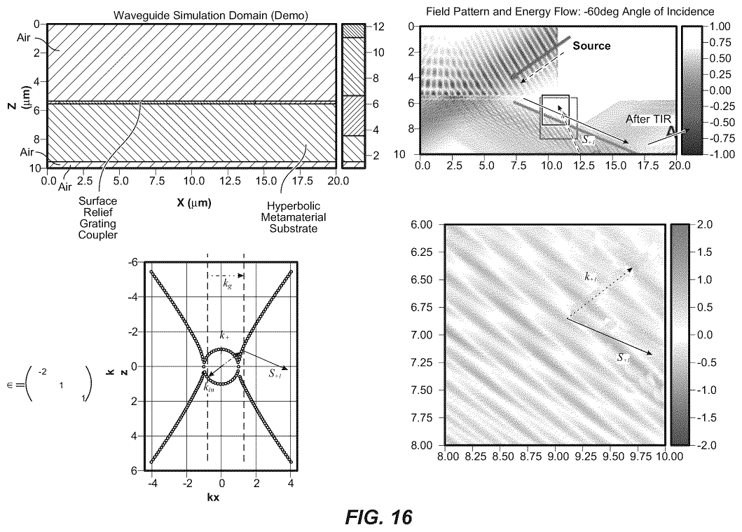

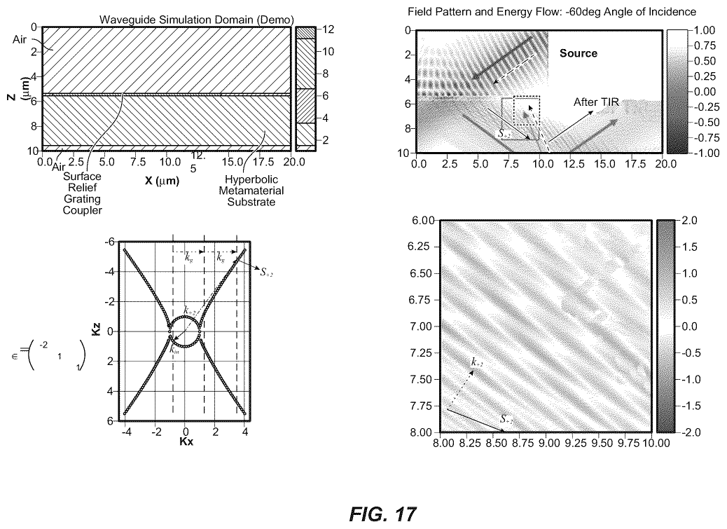

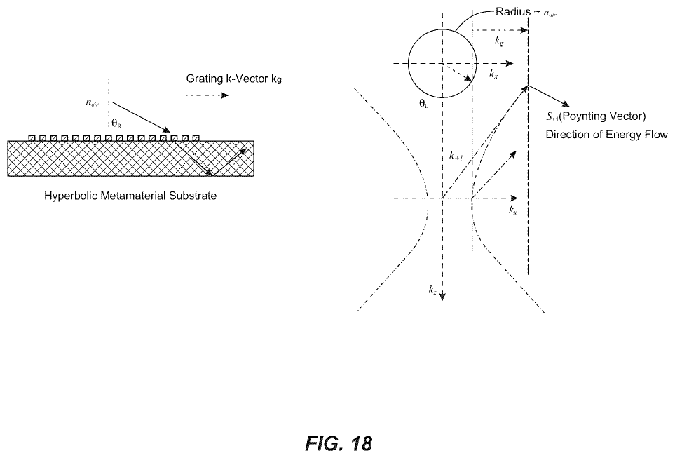

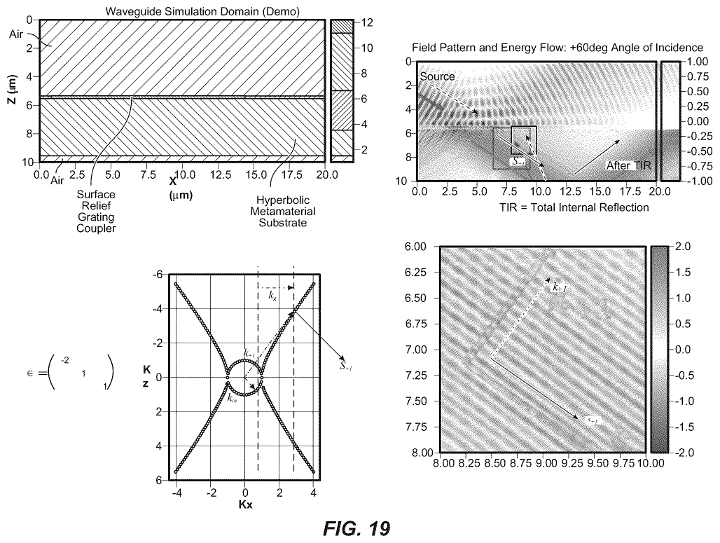

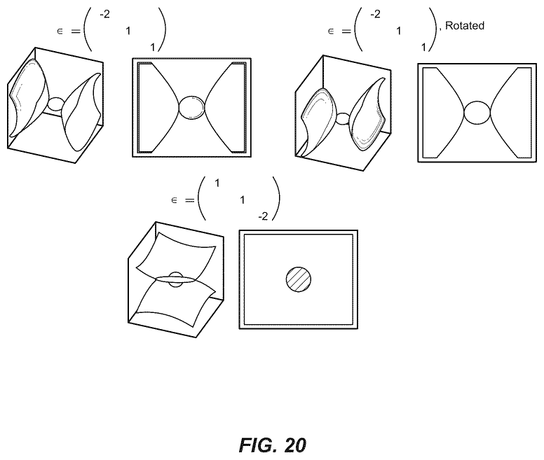

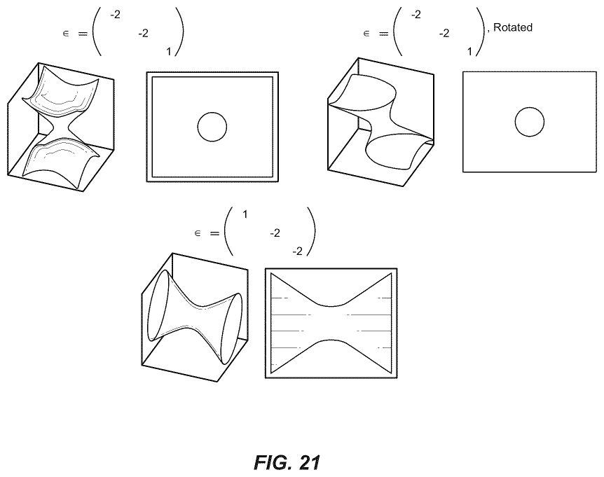

The following will provide, with reference to FIGS. 11-22, detailed descriptions of devices and related methods associated with a hyperbolic metamaterial-based waveguide display. The discussion associated with FIGS. 11-13 includes a description of diffractive waveguide fundamentals. The discussion associated with FIGS. 14-22 includes a description of diffractive waveguides including a hyperbolic metamaterial substrate and associated principles.

Referring to FIG. 11, shown is a schematic cross-sectional view of a representative diffractive waveguide. FIG. 11 illustrates the dependence of the waveguide's field-of-view on critical angle and grazing angle conditions. A k-space analysis showing the effects of refractive index on the field-of-view for a refractive waveguide is depicted in FIGS. 12 and 13.

Referring to FIG. 14, shown is a comparison of the relative permittivity tensors for isotropic and anisotropic optical materials with hyperbolic metamaterials. Depending on the polarization, hyperbolic metamaterials support k-vectors that lie on ellipsoids and hyperbola. For exemplary materials, the relative permittivity (ϵᵣ) is a tensor with at least one negative diagonal term.

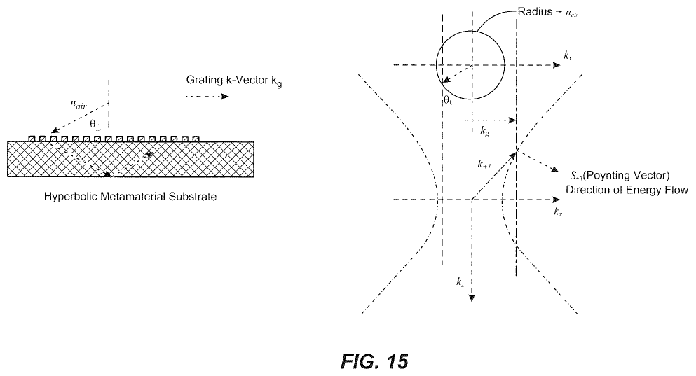

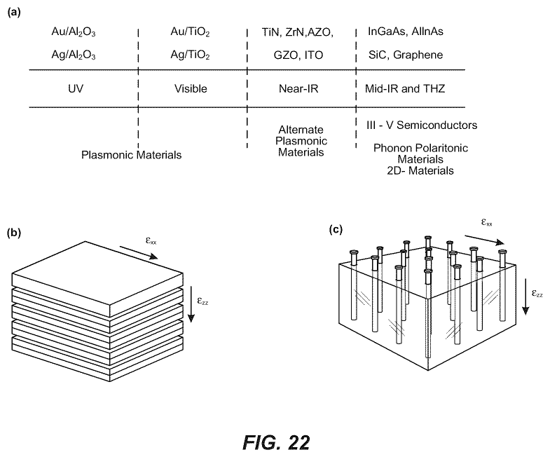

Referring to FIGS. 15-19, shown are k-space renderings for hyperbolic metamaterials and the modeled impact on the 1D field-of-view (FOV) for a diffractive waveguide having a substrate formed from such materials. Referring to FIGS. 20 and 21, hyperbolic metamaterials may also support an arbitrarily wide field-of-view in 2D, where the corresponding relative permittivity tensor may have one negative diagonal term or two negative diagonal terms. A diffractive waveguide display device having a hyperbolic metamaterial-containing waveguide substrate may have a diagonal field-of-view of at least approximately 45°, a horizontal field-of-view of at least approximately 180°, and a vertical field-of-view of at least approximately 120°. Hyperbolic metamaterials having thin film and nanowire architectures are depicted schematically in FIG. 22.

A diffractive waveguide includes a waveguide substrate formed from a hyperbolic metamaterial, and may advantageously exhibit an arbitrarily wide field of view (FOV). The hyperbolic metamaterial can be made with either 1 or 2 permittivity elements being negative and the hyperbolic axis arbitrarily rotated. Exemplary hyperbolic metamaterials can be engineered from subwavelength (i.e., nanoscale) metallic and dielectric layers or using an array of subwavelength metallic wires aligned within a dielectric matrix. An arbitrarily wide FOV can be supported across the full color spectrum due to the hyperbolic metamaterial's infinite x-y coverage in k-space. Higher order diffractions inside hyperbolic metamaterials can also contribute to the waveguiding of display light into a user's eyes.

### EXAMPLE EMBODIMENTS

Example 1: A waveguide display device includes a substrate including a hyperbolic metamaterial, and a grating structure overlying the substrate.

Example 2: The waveguide display device of Example 1, where the hyperbolic metamaterial includes multiple units of a symmetrical metal-dielectric bilayer.

Example 3: The waveguide display device of Example 1, where the hyperbolic metamaterial includes an array of nanoscale conductive wires embedded in a dielectric matrix.

Example 4: The waveguide display device of any of Examples 1-3, where a relative permittivity tensor for the hyperbolic metamaterial has a single negative diagonal term.

Example 5: The waveguide display device of any of Examples 1-3, where a relative permittivity tensor for the hyperbolic metamaterial has two negative diagonal terms.

Example 6: The waveguide display device of any of Examples 1-5, where a diagonal field-of-view of the waveguide display is at least approximately 45°.

Example 7: The waveguide display device of any of Examples 1-6, where a horizontal field-of-view of the waveguide display is at least approximately 180°.

Example 8: The waveguide display device of any of Examples 1-7, where a vertical field-of-view of the waveguide display is at least approximately 120°.

Example 9: An augmented reality display apparatus includes the waveguide display device of any of Examples 1-8.

### Production of Small Molecule Organic Solid Crystals Formed from a Melt at Elevated Pressure

Polymer and other organic materials may be incorporated into a variety of different optic and electro-optic systems and devices, including passive and active optics and electroactive devices. Lightweight and conformable, one or more polymer/organic solid layers may be incorporated into wearable devices such as smart glasses and are attractive candidates for emerging technologies including virtual reality/augmented reality devices where a comfortable, adjustable form factor is desired.

Virtual reality (VR) and augmented reality (AR) eyewear devices or headsets, for instance, may enable users to experience events, such as interactions with people in a computer-generated simulation of a three-dimensional world or viewing data superimposed on a real-world view. By way of example, superimposing information onto a field of view may be achieved through an optical head-mounted display (OHMD) or by using embedded wireless glasses with a transparent heads-up display (HUD) or augmented reality (AR) overlay. VR/AR eyewear devices and headsets may be used for a variety of purposes. Governments may use such devices for military training, medical professionals may use such devices to simulate surgery, and engineers may use such devices as design visualization aids.

Organic materials exhibiting optical anisotropy may be incorporated into a variety of systems and devices, including lenses, birefringent gratings, reflective polarizers, optical compensators and optical retarders for systems using polarized light such as liquid crystal displays (LCDs). Fresnel lenses may be used in wearable optics to focus light. Birefringent gratings may be used as optical combiners in augmented reality displays, for instance, and as input and output couplers for waveguides and fiber optic systems. Reflective polarizers may be used in many display-related applications, particularly in pancake optical systems and for brightness enhancement within display systems that use polarized light. For orthogonally polarized light, pancake lenses may use reflective polarizers with extremely high contrast ratios for transmitted light, reflected light, or both transmitted and reflected light.

Notwithstanding recent developments, it would be advantageous to provide single crystal organic materials and associated methods for their manufacture. In conjunction with various methods of manufacture, melt-based crystal growth processes may be used to produce sized organic solid crystals.

Due to their relatively low melting temperature, organic solid crystal materials may be molded to form a desired structure. Molding processes may enable the formation of complex architectures and may be more economical than the cutting, grinding, and polishing of bulk crystals. In one example, a single crystal shape such as a sheet or cube may be partially or fully melted into a desired form and then controllably cooled to form a single crystal having a new shape such as a lenticular or lens shape.

A process of molding an optically anisotropic crystalline or partially crystalline substrate, for example, may include operational control of the thermodynamics and kinetics of nucleation and crystal growth. In certain embodiments, a temperature during molding proximate to a nucleation region of a crystal growth chamber may be less than a melting onset temperature (Tₘ) of a molding composition, while the temperature remote from the nucleation region may be greater than the melting onset temperature. Such a temperature gradient paradigm may be obtained through a spatially applied thermal gradient, optionally in conjunction with a selective melting process (e.g., laser) to remove excess nuclei, leaving few nuclei (e.g., a single nucleus) for crystal growth. A system pressure during molding may be arranged to facilitate transport of a suitable feedstock into a crystal growth chamber as well as to inhibit CTE-induced cracking of an organic solid crystal during or after an act of molding.

To promote nucleation and crystal growth, a selected temperature and temperature gradient may be applied to a crystallization front of a nascent OSC substrate or thin film. For instance, the temperature and temperature gradient proximate to the crystallization front may be determined based on the selected feedstock (i.e., molding composition), including its melting temperature, thermal stability, and rheological attributes. A selected pressure may be in excess of atmospheric pressure.

An exemplary method includes introducing molten feedstock of an organic semiconductor into a crystal growth chamber, controlling a thermal gradient within the molten feedstock to form a solidification front, moving the solidification front within the crystal growth chamber to grow a single crystal including the organic semiconductor, and maintaining a pressure greater than atmospheric pressure within the crystal growth chamber while forming the single crystal.

A suitable chamber for molding an organic solid crystal substrate may be formed from a material having a softening temperature or a glass transition temperature (T_{g}) greater than the melting onset temperature (Tₘ) of the molding composition. The chamber may include any suitable material, e.g., silicon, silicon dioxide, fused silica, quartz, glass, nickel, silicone, siloxanes, perfluoropolyethers, polytetrafluoroethylenes, perfluoroalkoxy alkanes, polyimide, polyethylene naphthalate, polyvinylidene fluoride, polyphenylene sulfide, and the like.

The crystal growth chamber may include an inner surface that may be configured to provide a desired shape to the molded organic solid crystal. For example, the chamber surface may be planar, concave, or convex, and may include a three-dimensional architecture, such as surface relief gratings, facets, rings, or a curvature (e.g., compound curvature) suited to form microlenses, microprisms, or prismatic lenses. According to some embodiments, a chamber geometry may be transferred and incorporated into a surface of an over-formed organic solid crystal layer. Disclosed is a pressurized zone annealing process for growing oriented single crystal organic thin films.

The deposition surface of a crystal growth chamber may include a functional layer that is configured to be transferred to the organic solid crystal. Functional layers may include an interference coating, an AR coating, a reflectivity enhancing coating, a bandpass coating, a band-block coating, blanket or patterned electrodes, etc. By way of example, an electrode may include any suitably electrically conductive material such as a metal, a transparent conductive oxide (TCO) (e.g., indium tin oxide or indium gallium zinc oxide), or a metal mesh or nanowire matrix (e.g., including metal nanowires or carbon nanotubes).

An epitaxial or non-epitaxial growth process may be used to form an organic solid crystal. A seed crystal for encouraging crystal nucleation and an anti-nucleation layer configured to locally inhibit nucleation may collectively promote the formation of a limited number of crystal nuclei within one or more specified location(s) within a crystal growth chamber, which may in turn encourage the formation of larger organic solid crystals. In some embodiments, a nucleation-promoting layer or seed crystal may be configured as a thin film.

As used herein, the terms “epitaxy,” “epitaxial” and/or “epitaxial growth and/or deposition” refer to the nucleation and growth of an organic solid crystal on a deposition surface where the organic solid crystal layer being grown assumes the same crystalline habit as the material of the deposition surface. For example, in an epitaxial deposition process, chemical reactants may be controlled, and the system parameters may be set so that depositing atoms or molecules alight on the deposition surface and remain sufficiently mobile via surface diffusion to orient themselves according to the crystalline orientation of the atoms or molecules of the deposition surface. An epitaxial process may be homogeneous or heterogeneous.

Example nucleation-promoting or seed materials may include one or more metallic or inorganic elements or compounds, such as Pt, Ag, Au, Al, Pb, indium tin oxide, SiO₂, and the like. Further example nucleation-promoting or seed crystal materials may include organic compounds, such as a polyimide, polyamide, polyurethane, polyurea, polythiolurethane, polyethylene, polysulfonate, polyolefin, as well as mixtures and combinations thereof. In some examples, a nucleation-promoting material may be configured as a textured or aligned layer, such as a rubbed polyimide or photoalignment layer, which may be configured to induce directionality or a preferred orientation to an over-formed organic solid crystal layer.

Another example of a nucleation-promoting or seed material may include a crystal made from the same organic molecule as that being molded, where the nucleation-promoting or seed material may be positioned and oriented to provide desired crystal properties. Whereas some degree of melting of the nucleation-promoting or seed material may be desired to reduce the impact of defects on the crystal surface, the seed crystal may be locally cooled to prevent or limit melting when put in contact with the melt. Alternatively, the nucleation-promoting or seed material may be a different crystalline organic or inorganic material, and may have a higher melting point than the feedstock material.

An anti-nucleation layer may include a dielectric material. In further embodiments, an anti-nucleation layer may include an amorphous material. In example processes, homogeneous or heterogeneous crystal nucleation may occur independent of a deposition surface with a crystal growth chamber.

An example method for manufacturing an organic solid crystal includes providing a crystal growth chamber, forming a layer of a nucleation-promoting material over at least a portion of a surface of the chamber, and depositing a layer of molten feedstock over the surface of the chamber and in contact with the layer of the nucleation-promoting material, while maintaining a temperature gradient across the layer of the molten feedstock and a desired pressure within the chamber.

In some embodiments, a surface treatment or release layer disposed over an inner surface of the chamber may be used to control nucleation and growth of the organic solid crystal (OSC) and later promote separation and harvesting of a bulk crystal. For instance, a coating having a solubility parameter mismatch with the deposition chemistry may be applied to the chamber inner surface (e.g., globally or locally) to suppress interaction between the chamber and the crystallizing layer during the deposition process.

Example surface treatment coatings may include oleophobic coatings or hydrophobic coatings. A thin layer, e.g., monolayer or bilayer, of an oleophobic material or a hydrophobic material may be used to condition the chamber prior to an epitaxial process. The coating material may be selected based on the chamber and/or the organic crystalline material. Further example surface treatment coating materials include siloxanes, fluorosiloxanes, phenyl siloxanes, fluorinated coatings, polyvinyl alcohol, and other OH bearing coatings, acrylics, polyurethanes, polyesters, polyimides, inorganic glasses, and the like.

In some embodiments, a release agent may be applied to an internal surface of the chamber and/or combined with the molding composition. A surface treatment of an inner surface of the chamber may include the chemical bonding or physical adsorption of small molecules, or polymers/oligomers having linear, branched, dendritic, or ringed structures, that may be functionalized or terminated, for example, with fluorinated groups, silicones, or hydrocarbon groups.

A buffer layer may be formed over the deposition surface of a chamber. A buffer layer may include a small molecule that may be similar to or even equivalent to the small molecule forming the organic solid crystal, e.g., an anthracene single crystal. A buffer layer may be used to tune one or more properties of the deposition/growth surface of the chamber, including surface energy, wettability, crystalline or molecular orientation, etc.

In some embodiments, an additive may be used to encourage the growth of a single crystal and/or its release from the chamber. In some embodiments, in addition to the precursor material (i.e., crystallizable organic molecules) used to form the organic solid crystal, a feedstock may include an additive selected from polymers, oligomers, and small molecules, where the additive may have a melting onset temperature of at least 20° C. less than a melting onset temperature of the organic solid crystal precursor, e.g., 20° C., 30° C., or even 40° C. less than the melting onset temperature of the molding composition. An additive may promote crystal growth and the formation of a large crystal size. In some embodiments, an additive may be integrated with a molding process to improve the characteristics of a molded organic solid crystal, including its surface roughness.

A further example method for manufacturing an organic solid crystal includes forming a layer of a molecular feedstock over a surface of a crystal growth chamber, the molecular feedstock including crystallizable organic molecules, forming a selected number of crystal nuclei from the organic molecules within a nucleation region of the molecular feedstock layer, and growing the selected number of crystal nuclei to form an organic solid crystal. In some embodiments, the selected number of crystal nuclei may be one. Crystal growth may be controlled using an isothermal process, slow cooling, and zone annealing.

During nucleation and growth, the orientation of the in-plane axes of an OSC layer may be controlled using one or more of mold temperature, deposition pressure, solvent vapor pressure, or non-solvent vapor pressure. Crystal orientation control may also be achieved by patterning of the chamber surface, or by the addition of a passivation layer or alignment layer to the chamber. High refractive index and highly birefringent organic solid crystal materials may be supported by a mold or removed therefrom to form a free-standing article. A mold, if used, may be rigid or deformable.

Example processes may be integrated with a real-time feedback loop that is configured to assess one or more attributes of the organic solid crystal and accordingly adjust one or more process variables, including melt temperature, mold temperature, feedstock injection rate into a mold, chamber pressure, etc.

Following deposition, an OSC layer may be diced and polished to achieve a desired form factor and surface quality. Dicing may include diamond turning, for example, although other cutting methods may be used. Polishing may include chemical mechanical polishing. In some embodiments, a chemical or mechanical surface treatment may be used to create structures on a surface of an OSC layer. Example surface treatment methods include diamond turning and photolithography and etch processes. In some embodiments, a cover plate or mold located within the crystal growth chamber and having reciprocal structures may be used to fabricate surface structures in an over-formed organic solid crystal.

An organic solid crystal may include a surface that is planar, convex, or concave. In some embodiments, the surface may include a three-dimensional architecture, such as a periodic surface relief grating or surface facets. In further embodiments, an organic solid crystal may be configured as a microlens or a prismatic lens. For instance, polarization optics may include a microlens that selectively focuses one polarization of light over another. In some embodiments, a structured surface may be formed in situ, i.e., during crystal growth of the organic solid crystal material over a suitably shaped mold. Accordingly, an OSC material having a structured surface may be characterized as having a unitary construction. In further embodiments, a structured surface may be formed after crystal growth, e.g., using additive or subtractive processing, such as 3D printing or photolithography and etching.

The nucleation and growth kinetics and choice of chemistry may be selected to produce a solid organic single crystal having dimensions that independently range from approximately 10 nm to approximately 5 cm. For instance, an OSC thin film or plate may have a thickness ranging from approximately 10 nm to approximately 500 micrometers, e.g., 10, 20, 50, 100, 200, 500, 1000, 2000, 5000, 10000, 20000, 50000, 100000, 200000, or 500000 nm, including ranges between any of the foregoing values, and areal dimensions independently ranging from approximately 10 nm to approximately 5 cm or more, e.g., 10, 20, 50, 100, 200, 500, 1000, 2000, 5000, 10000, 20000, 50000, 100000, 200000, 500000, 1000000, 2000000, 5000000, 10000000, 20000000, or 50000000 nm, including ranges between any of the foregoing values.

One or more source materials may be used to form an organic solid crystal. Example organic materials include various classes of crystallizable organic semiconductors. In accordance with various embodiments, organic semiconductors may include small molecules, macromolecules, liquid crystals, organometallic compounds, oligomers, and polymers. Organic semiconductors may include p-type, n-type, or ambipolar polycyclic aromatic hydrocarbons, including polyacene compounds such as anthracene, naphthalene, phenanthrene, carbon 60, pyrene, corannulene, fluorene, tetracene, pentacene, biphenyl, terphenyl, etc.

Example compounds may include cyclic, linear and/or branched structures, which may be saturated or unsaturated, and may additionally include heteroatoms and/or saturated or unsaturated heterocycles, such as furan, pyrrole, thiophene, pyridine, pyrimidine, piperidine, and the like. Heteroatoms may include fluorine, chlorine, nitrogen, oxygen, sulfur, phosphorus, as well as various metals. Example compounds may be crystallographically non-centrosymmetric.

Structurally, the disclosed organic solid crystal materials may be single crystal or polycrystalline. Organic solid crystals may include closely packed structures (e.g., organic molecules) that exhibit desirable optical properties such as a high and tunable refractive index, and high birefringence. Anisotropic organic solid materials may include a preferred packing of molecules or a preferred orientation or alignment of molecules.

Such organic solid crystal (OSC) materials may provide functionalities, including phase modulation, beam steering, wave-front shaping and correction, optical communication, optical computation, holography, and the like. Due to their optical and mechanical properties, organic solid crystals may enable high-performance devices, and may be incorporated into passive or active optics, including AR/VR headsets, and may replace comparative material systems in whole or in part, such as polymers, inorganic materials, and liquid crystals. In certain aspects, organic solid crystals may have optical properties that rival those of inorganic crystals while exhibiting the processability and electrical response of liquid crystals.

In some embodiments, an organic solid crystal material may have three principal indices of refraction, where at least two indices are different from each other (e.g., nₓ=n_{y}≈n_{z}, nₓ=n_{z}≈n_{y}, n_{y}=n_{z}≈nₓ, or nₓ≈n_{y}≈n_{z}). The organic crystalline phase may be characterized by a refractive index along at least one principal axis of at least approximately 1.4 at 589 nm. By way of example, the refractive index of the organic crystalline phase at 589 nm and along at least one principal axis may be at least approximately 1.4, at least approximately 1.5, at least approximately 1.6, at least approximately 1.7, at least approximately 1.8, at least approximately 1.9, at least approximately 2.0, at least approximately 2.1, at least approximately 2.2, at least approximately 2.3, at least approximately 2.4, at least approximately 2.5, or at least approximately 2.6, including ranges between any of the foregoing values.

In some embodiments, the organic crystalline phase may be characterized by a birefringence (Dn), where nₓ≈n_{y}≈n_{z}, nₓ=n_{y}≈n_{z}, nₓ≈n_{y}=n_{z}, or nₓ=n_{z}≈n_{y}, of at least approximately 0.05, e.g., at least approximately 0.05, at least approximately 0.1, at least approximately 0.2, at least approximately 0.3, at least approximately 0.4, or at least approximately 0.5, including ranges between any of the foregoing values. In some embodiments, a birefringent organic crystalline phase may be characterized by a birefringence of less than approximately 0.05, e.g., less than approximately 0.05, less than approximately 0.02, less than approximately 0.01, less than approximately 0.005, less than approximately 0.002, or less than approximately 0.001, including ranges between any of the foregoing values.

Organic solid crystals may be incorporated into active and passive optical waveguides, resonators, lasers, optical modulators, etc. Further example active optics include projectors and projection optics, ophthalmic high index lenses, eye-tracking, gradient-index optics, Pancharatnam-Berry phase (PBP) lenses, microlenses, pupil steering elements, optical computing, fiber optics, rewritable optical data storage, all-optical logic gates, multi-wavelength optical data processing, optical transistors, etc. According to further embodiments, organic solid crystals may be incorporated into passive optics, such as waveguides, reflective polarizers, refractive/diffractive lenses, and the like. Related optical elements for passive optics may include waveguides, polarization selective gratings, Fresnel lenses, microlenses, geometric lenses, PBP lenses, and multilayer thin films.

As will be appreciated, one or more characteristics of organic solid crystals may be specifically tailored for a particular application. For many optical applications, it may be advantageous to control crystallite size, surface roughness, mechanical strength and toughness, and the orientation of crystallites and/or molecules within an organic solid crystal.

According to various embodiments, an optical element including an organic solid crystal (OSC) may be integrated into an optical component or device, such as an OFET, OPV, OLET, OLED, etc., and may be incorporated into a structure or a device such as a waveguide, Fresnel lens (e.g., a cylindrical Fresnel lens or a spherical Fresnel lens), grating, photonic integrated circuit, birefringent compensation layer, reflective polarizer, index matching layer (LED/OLED), and the like. In certain embodiments, grating architectures may be tunable along one, two, or three dimensions. Optical elements may include a single layer or a multilayer OSC architecture.

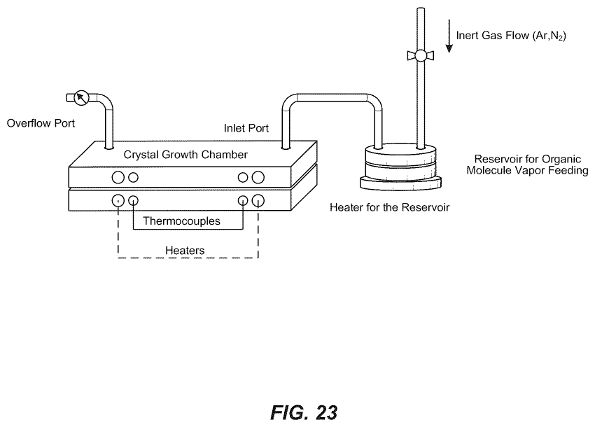

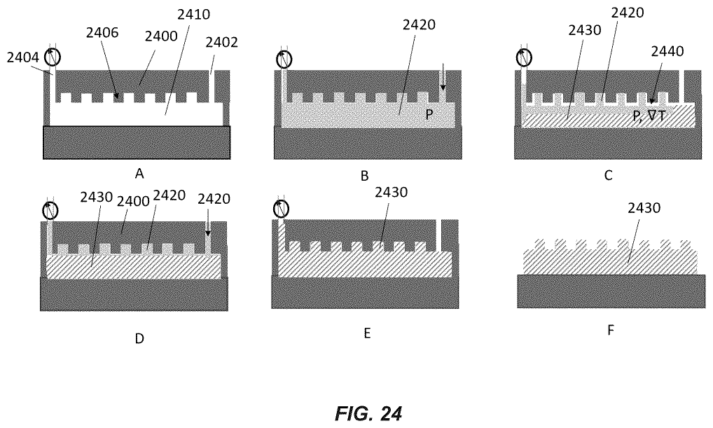

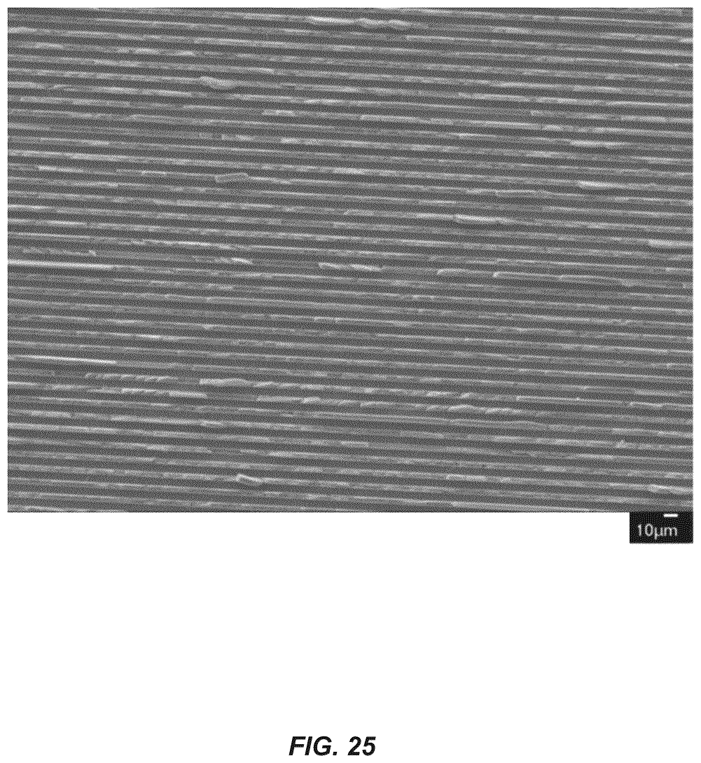

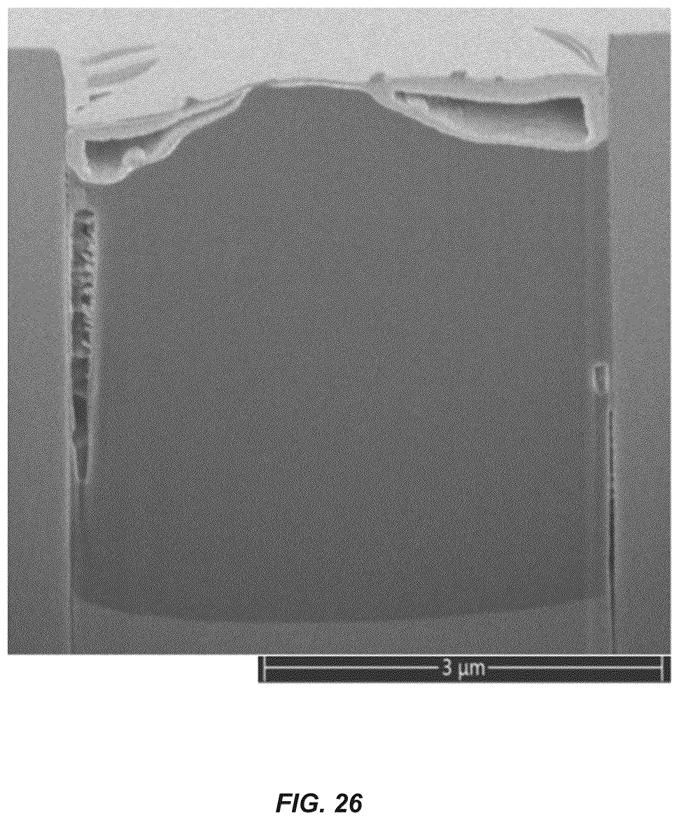

The following will provide, with reference to FIGS. 23-26, detailed descriptions of apparatus and methods for the manufacture of organic solid crystals, as well as resulting structures. The discussion associated with FIGS. 23 and 24 includes a description of a crystal growth chamber and a method for forming a single crystal OSC material. The discussion associated with FIGS. 25 and 26 includes a description of an organic solid crystal having a structured surface as disclosed herein.

Referring to FIG. 23, shown is a perspective view of an example system for forming an organic solid crystal from molten feedstock. The system includes a crystal growth chamber having an inlet port and an overflow port for mediating the content and pressure of the molten feedstock within the chamber. Thermocouple and heater arrays may be configured to control the temperature and the temperature gradient of the molten feedstock within the crystal growth chamber. In the illustrated embodiment, a separate melt reservoir may be used to form the molten feedstock, e.g., from a gaseous precursor. An inert gas may be used to propel the molten feedstock through the inlet port into the crystal growth chamber at a desired pressure. In some embodiments, the crystal growth chamber may be completely filled or substantially filled with the molten feedstock during an act of forming a crystalline solid.

Turning to FIG. 24, shown is an example apparatus and method for forming an organic solid crystal having a structured surface. Referring to FIG. 24A, a mold 2400 may define a crystal growth chamber 2410. Mold 2400 may include an inlet port 2402 for introducing molten feedstock into the chamber 2410 and an overflow port 2404 for controlling the content and pressure (P) of the molten feedstock within the chamber. An inner surface of the chamber 2410 may include structured features 2406.

Referring to FIG. 24B, a volume of molten feedstock 2420 may be fed into the chamber 2410 via inlet port 2402 at a controlled pressure (P) to fill or substantially fill the chamber 2410. As shown in FIG. 24C, the temperature of the molten feedstock 2420 may be controlled to initiate nucleation and crystal growth of a suitably oriented organic solid crystal 2430 within the chamber 2410. A temperature gradient may create a crystal growth front that is swept across the feedstock volume. An elevated and substantially constant pressure (P) may be maintained within the crystal growth chamber 2410 throughout the act of forming a single crystal.

As shown schematically in FIG. 24C, a decrease in volume of the nascent crystal relative to the molten feedstock may accompany the liquid-to-solid phase transformation, which may decrease a total volume of the organic material within the chamber. In some embodiments, as shown in FIG. 24D, during growth of organic solid crystal 2430, additional molten feedstock may be introduced into the mold 2400 to fill gaps 2440 between the feedstock and the mold 2400, e.g., proximate to structured features 2406. Elevated pressure within the crystal growth chamber 2410 may direct the newly-introduced molten feedstock into gaps 2440.

As shown in FIG. 24E, crystal growth may continue such that the crystal 2430 grows into the openings between the structured features 2406 of the mold 2400 to form a single crystal having a structured surface. Referring to FIG. 24F, the organic solid crystal 2430 may be removed from the mold 2400. A scanning electron microscope (SEM) image of a molded organic solid crystal having a structured surface is shown in FIG. 25. An SEM image of a focused ion beam-diced channel structure having OSC material filling the channel is shown in FIG. 26.

Disclosed is a method for forming organic solid crystal (OSC) structures, including thin films, gratings, and photonic components. In exemplary embodiments, molten feedstock of a suitable organic semiconductor may be fed into a growth chamber at elevated pressure and directionally solidified to form a structurally and functionally engineered single crystal. Organic semiconductors may include polycyclic aromatic compounds, for example, such as anthracene, phenanthrene, pyrene, and the like.

The growth chamber may include a structured inner surface that is configured to template a desired surface profile in the molded crystal. Molecular orientation of the OSC layer may be controlled via surface modification of the inner surface of the growth chamber or through use of a seed crystal. The OSC crystal may be removed from the growth chamber as a free-standing structure or grown and co-integrated onto a substrate. An elevated pressure within the growth chamber during and after crystal growth may facilitate transport of the molten feedstock into the crystal growth chamber and the growth of a single crystal. Also, elevated pressures may influence the morphology and phase of the organic solid crystal. Moreover, an elevated pressure may discourage CTE-induced cracking of the newly-formed crystal upon cooling.

The process may be integrated with a real-time feedback loop that is configured to assess one or more attributes of the organic solid crystal and accordingly adjust one or more process variables. Resultant structures may include single layer or multilayer OSC architectures, and may be incorporated into optical elements such as AR/VR headsets and other devices, e.g., waveguides, Fresnel lenses, reflective polarizers, projectors and projection optics, etc.

### EXAMPLE EMBODIMENTS

Example 1: A method includes introducing molten feedstock including an organic semiconductor into a crystal growth chamber, controlling a thermal gradient within the molten feedstock to form a solidification front, moving the solidification front within the crystal growth chamber to grow a single crystal including the organic semiconductor, and maintaining a pressure in excess of atmospheric pressure within the crystal growth chamber while forming the single crystal.

Example 2: The method of Example 1, including forming the molten feedstock outside of the crystal growth chamber.

Example 3: The method of any of Examples 1 and 2, where the molten feedstock substantially fills the crystal growth chamber prior to forming the solidification front.

Example 4: The method of any of Examples 1-3, where the molten feedstock is introduced into the crystal growth chamber during growth of the single crystal.

Example 5: The method of any of Examples 1-4, where the organic semiconductor includes a polycyclic aromatic hydrocarbon.

Example 6: The method of any of Examples 1-5, where the organic semiconductor includes a molecule selected from anthracene, naphthalene, phenanthrene, carbon 60, pyrene, corannulene, fluorene, tetracene, pentacene, biphenyl, and terphenyl.

Example 7: The method of any of Examples 1-6, where the pressure within the crystal growth chamber is greater than approximately 150 Pa while forming the single crystal.

Example 8: The method of any of Examples 1-7, where the pressure in excess of atmospheric pressure is maintained during cooling of the single crystal.

Example 9: The method of any of Examples 1-8, where the single crystal is a plate having a thickness of at least approximately 10 nm.

Example 10: The method of any of Examples 1-9, where the single crystal is a plate having an areal dimension of at least approximately 10 nm.

Example 11: The method of any of Examples 1-10, where the single crystal is grown on a substrate.

Example 12: The method of any of Examples 1-11, where the single crystal is grown over a structured surface.

Example 13: The method of any of Examples 1-12, including removing the single crystal from the crystal growth chamber and mounting the single crystal on a substrate.

Example 14: An article includes an organic solid single crystal having a structured surface and mutually-orthogonal refractive indices, nₓ, n_{y}, n_{z}, where the single crystal has an average thickness of at least approximately 10 nm, a length of at least approximately 10 nm, and a width of at least approximately 10 nm.

Example 15: The article of Example 14, where the average thickness is at least approximately 50 micrometers, the length is at least approximately 50 micrometers, and the width is at least approximately 50 micrometers.

Example 16: The article of any of Examples 14 and 15, where the single crystal includes a polycyclic aromatic hydrocarbon.

Example 17: The article of any of Examples 14-16, where nₓ=n_{y}≈n_{z}, nₓ=n_{z}≈n_{y}, n_{y}=n_{z}≈nₓ, or nₓ≈n_{y}≈n_{z}.

Example 18: The article of any of Examples 14-17, where nₓ>n_{z}>n_{y}.

Example 19: A method includes forming a single crystal including an organic semiconductor within a crystal growth chamber, where during formation of the single crystal a pressure within the crystal growth chamber is greater than atmospheric pressure.

Example 20: The method of Example 19, where the pressure in excess of atmospheric pressure is maintained during cooling of the single crystal

Across various optical engineering applications including eyeglasses, contact lenses, and vision correction elements in augmented reality (AR) and virtual reality (VR) systems, liquid crystal (LC) lenses may provide a number of advantages due to their electrically tunable focusing capability, where the associated optical mechanism is based on a spatially localized modulation of light speed resulting from LC molecular orientations driven by applied electric fields.

In such context, and as will be appreciated, the realization of a continuous distribution of phase retardation across larger aperture (>10 mm) LC lenses may be challenged by the limited birefringence (<0.4) of LC materials as well as their mechanically compliant nature. In some embodiments, a gradient-index configuration may be used to provide tunability of focus quality.

Gradient-index (GRIN) optics refers to a branch of optics where optical effects are produced by a spatial gradient in the refractive index of a material. A gradual refractive index variation may be used to manufacture lenses having planar surfaces, for example, or to reduce aberrations in imaging applications. In an LC lens having an axial gradient configuration, the refractive index may vary along the optical axis of an inhomogeneous medium such that surfaces of constant index are planes that are oriented perpendicular to the optical axis. In a radial/cylindrical refractive index gradient configuration, on the other hand, the index profile may vary continuously from a centerline of the optical axis to the periphery along the transverse direction in such a way that surfaces of constant index are concentric cylinders located about the optical axis. Hybrid GRIN LC lenses having both an axial and a radial/cylindrical refractive index gradient configuration are also contemplated.

A gradient refractive index lens utilizes a spatially-defined refractive index gradient across the viewing aperture of the lens to impart an optical phase profile at a selected design wavelength. In particular examples, a GRIN lens may have a planar form factor, such as a disk shape, and lensing performance that may be improved relative to lenses formed from a material having a single, spatially-invariant index, such as comparative lenses made from glass or quartz.

GRIN-type varifocal LC lenses may be configured to exhibit a gradient distribution of refractive index in response to a spatially inhomogeneous electric field that is applied across the LC layer(s). As such, the lens power of a GRIN-type LC lens may also be continuously tunable. In some instantiations, there may be a continuous variation of the refractive index within the lens material. An LC lens may be configured in both planar and non-planar (e.g., concave or convex) geometries.

In some systems, a tunable architecture may include a plurality of discrete, ring electrodes formed over the LC layer(s) within the optical aperture of the lens. During operation, a different voltage may be applied to each electrode, which may be used to locally tune the refractive index of the LC material. However, the patterning of multiple electrodes may create manufacturing challenges and also induce performance liabilities, including a loss of transmission, a decrease in focal power, and/or the generation of optical artifacts such as haze and/or ghosting due to angular diffraction arising from sub-critical electrode dimensions or the gap between neighboring electrodes. In some embodiments, the inter-electrode gaps across the viewing aperture of a varifocal GRIN LC lens may be greater than approximately 1 micrometer.

As used herein, the terms “haze” and “clarity” may refer to optical phenomena associated with the transmission of light through a material, and may be attributed, for example, to the refraction of light within the material, e.g., due to secondary phases or porosity and/or the reflection of light from one or more surfaces of the material. As will be appreciated by those skilled in the art, haze may be associated with an amount of light that is subject to wide angle scattering (i.e., at an angle greater than 2.5° from normal) and a corresponding loss of transmissive contrast, whereas clarity may relate to an amount of light that is subject to narrow angle scattering (i.e., at an angle less than 2.5° from normal) and an attendant loss of optical sharpness or “see through quality.”

Notwithstanding recent developments, it would be advantageous to provide a manufacturable and economical GRIN LC lens design that is configured to operate without the generation of significant haze or ghosting, or a loss of transmission. Such a GRIN LC lens design may be configured to provide a high varifocal range with high optical power and commercially relevant response times across a large aperture. The present disclosure thus relates to large aperture (diameter˜50 mm) GRIN LC lenses operable with rapid switching times (<1 sec) over a large optical power range (e.g., 0 to 3 Diopters).

Within a chosen viewing optic assembly, a GRIN LC component may be exposed to light across a range of incident angles that are unique to the viewing optic prescription.

According to various embodiments, when integrated into a viewing optic module, the GRIN LC phase profile may be configured to decrease monochromatic aberrations of the viewing optic module across the entire range of the incident angles. This modified phase profile may be essentially non-parabolic. Such an optical phase profile may advantageously decrease the number of required Fresnel resets, which otherwise contribute to the degradation of image quality, e.g., with respect to transmission, diffraction, and/or scattering.

In particular embodiments, disclosed is a GRIN LC component having an optical phase profile that obviates the diffraction of image light created by sub-critical electrode widths or inter-electrode spacings, notably at or proximate to the periphery of the lens, while also avoiding a defocus condition, which may be attributable to a spatially de-tuned optical power. A desired optical phase profile may be created using photolithography and etching to define a suitable electrode pattern.

By way of example, across a fixed dioptric range, the optical phase profile may be hyperbolic, which can decrease the density of Fresnel resets by approximately 20 to 25%, thereby improving off-axis modulation transfer function (MTF) performance. In an example 1D hyperbolic co-design, the number of phase drops within a 42 mm aperture may be decreased by approximately 25% relative to a 1D parabolic phase lens. The hyperbolic co-design is configured to lessen the total amount of light diffracted by the GRIN LC lens. In an example lens, the hyperbolic slope may be characterized by a 4th order polynomial, which may share some commonality with the 2^{nd} order parabolic slope. Relative to comparative GRIN LC lenses, the presently-disclosed architectures may exhibit improved optical performance, including decreased bulk haze and parallax, as well as improved manufacturability and cost.

According to some embodiments, a GRIN LC component may be configured to exhibit spatially varying viewing optics and an attendant variation in the effective optical phase profile. The associated phases may be parabolic, hyperbolic, or elliptical, for example, depending on the angle(s) of incident light and the desired optical power. According to some embodiments, a GRIN LC component includes a continuous hyperbolic optical phase profile, i.e., from center to edge. According to further embodiments, a GRIN LC lens may be characterized by a hybrid optical phase profile, i.e., a hybrid profile characterized as parabolic near the lens center and increasingly hyperbolic nearer to and approaching the periphery of the lens.

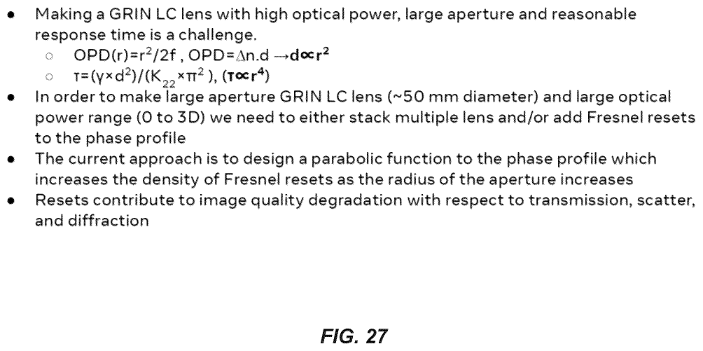

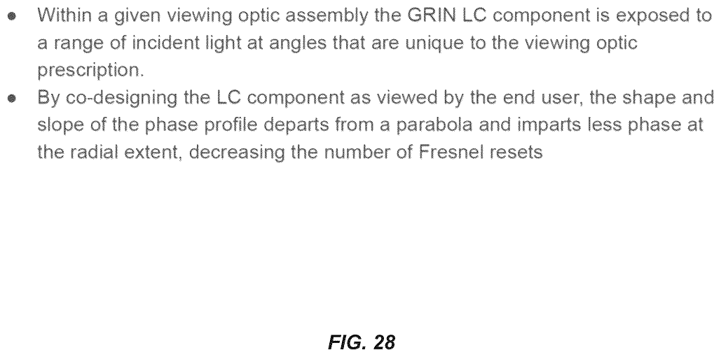

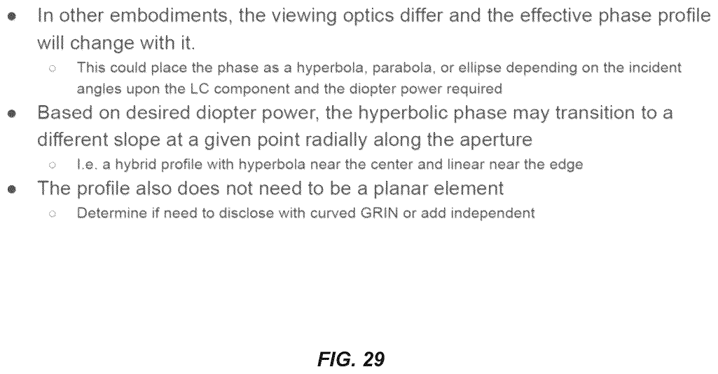

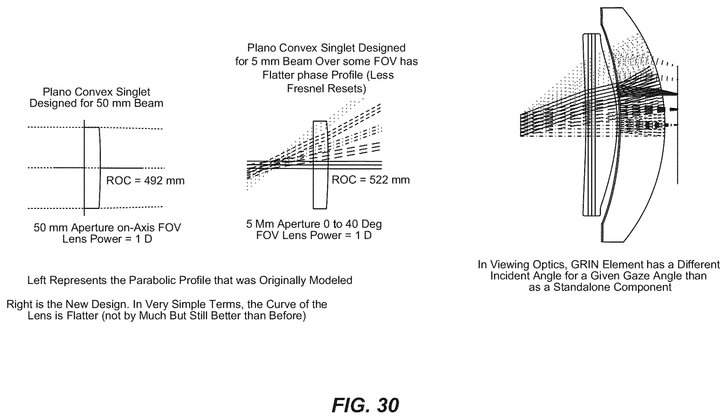

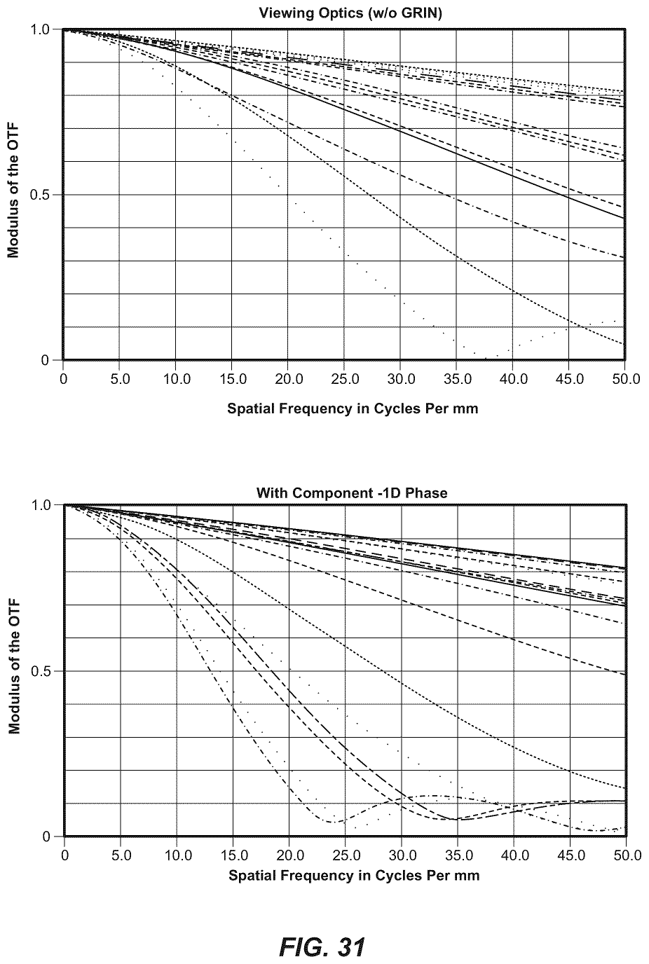

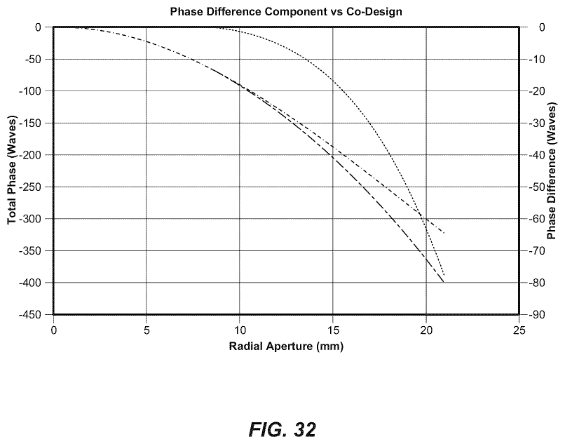

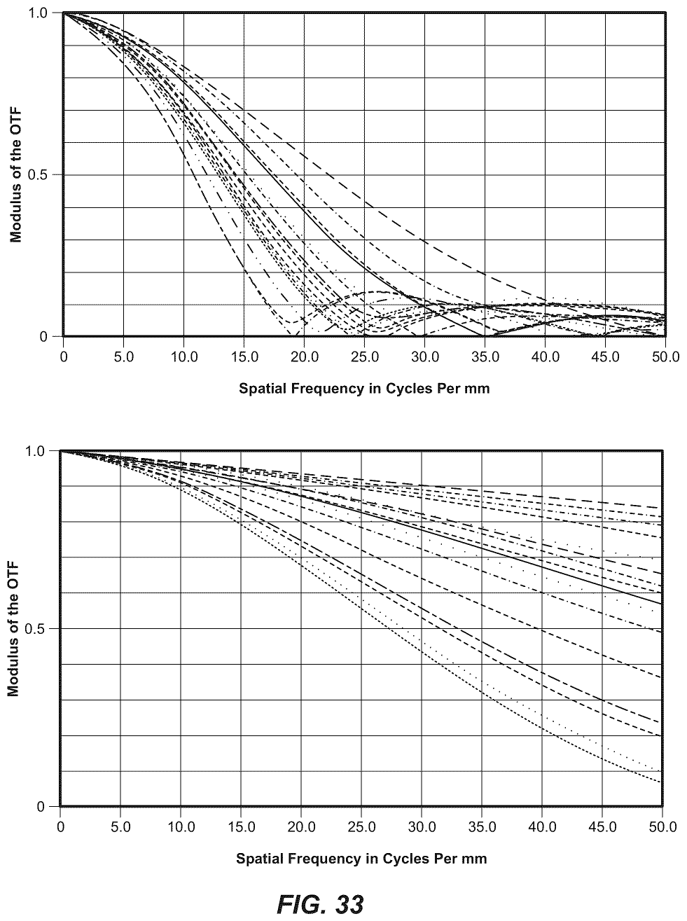

Turning to FIG. 27, shown is a review of various considerations in the design and manufacture of a large area GRIN LC lens. FIG. 28 shows a description of example GRIN LC lens architectures according to some embodiments. FIG. 29 shows a description of GRIN LC lens architectures according to further embodiments. FIG. 30 shows modeling results for GRIN LC lenses according to various embodiments. FIG. 31 shows plots of optical performance for various GRIN LC lens architectures according to some embodiments. FIG. 32 shows a plot of the total phase and the phase difference component as a function of radial position for example GRIN LC lenses according to certain embodiments. FIG. 33 shows the optical performance for parabolic and hyperbolic phase elements according to some embodiments.

Example 1: An optical element includes a first optical substrate, a second optical substrate overlying at least a portion of the first optical substrate, a liquid crystal layer disposed between the first optical substrate and the second optical substrate, a first patterned electrode layer disposed between the liquid crystal layer and the first optical substrate, and a second patterned electrode layer disposed between the liquid crystal layer and the second optical substrate, where at least one of the patterned electrode layers is configured to define a continuous optical phase profile across a viewing aperture of the optical element.

Example 2: The optical element of Example 1, where the first and second optical substrates include glass.

Example 3: The optical element of any of Examples 1 and 2, where the continuous optical phase profile includes a hyperbolic optical phase profile.

Example 4: The optical element of any of Examples 1-3, where at least one of the patterned electrodes is configured to define a central region within the viewing aperture having a first optical phase profile, and a region within the viewing aperture peripheral to the central region having a second optical phase profile.

Example 5: The optical element of Example 4, where the central region and the region peripheral to the central region are transparent at any design wavelength.

Example 6: The optical element of any of Examples 4 and 5, where the first optical phase profile includes an aspheric optical phase profile.

Example 7: The optical element of any of Examples 4-6, where the first optical phase profile is defined by a single polynomial equation.

Example 8: The optical element of any of Examples 4-7, where the second optical phase profile includes a hyperbolic optical phase profile or a linear optical phase profile.

Example 9: An optical module comprising the optical element of any of Examples 1-8, where the first and second optical phase profiles are configured to decrease monochromatic aberrations for all angles of light incident upon the viewing aperture.

Example 10: An augmented reality (AR) or virtual reality (VR) system including an AR or VR headset, and a variable power lens including the optical element of any of Examples 1-8.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

While various features, elements or steps of particular embodiments may be disclosed using the transitional phrase “comprising,” it is to be understood that alternative embodiments, including those that may be described using the transitional phrases “consisting of” or “consisting essentially of,” are implied. Thus, for example, implied alternative embodiments to a low refractive index material that comprises or includes silicon nitride include embodiments where a low refractive index material consists essentially of silicon nitride and embodiments where a low refractive index material consists of silicon nitride.

What is claimed is:

1. An optical element comprising:
a planar body having a circular profile comprising a plurality of annuli of decreasing width with increasing radius, wherein the circular profile comprises a sequential arrangement of:
(a) a first annulus comprising alternating azimuthal segments of high and low refractive index materials,
(b) a second annulus comprising the high refractive index material,
(c) a third annulus comprising alternating azimuthal segments of the high and low refractive index materials, and
(d) a fourth annulus comprising the low refractive index material.

2. The optical element of claim 1, wherein a fill factor of the first annulus is approximately 0.5, and a fill factor of the third annulus is approximately 0.5.

3. The optical element of claim 1, wherein the second annulus consists essentially of the high refractive index material, and the fourth annulus consists essentially of the low refractive index material.

4. The optical element of claim 1, wherein the high refractive index is greater than approximately 3.2 and the low refractive index is less than approximately 2.6.

5. The optical element of claim 1, wherein a center of the circular profile comprises the low refractive index material.

6. A light emitting diode package comprising the optical element of claim 1.

7. The light emitting diode package of claim 6, wherein the circular profile is centered about an optical axis of the light emitting diode.

8. An optical element comprising:
a planar body having a circular profile comprising a plurality of annuli of decreasing width with increasing radius, wherein the circular profile comprises an alternating arrangement of structured and unstructured annuli, the structured annuli comprising alternating azimuthal segments of high and low refractive index materials and the unstructured annuli comprising a high refractive index material or a low refractive index material.
